(19) United States
(12) Patent Application Publication
(10) Pub. No.: US 2026/0156921 A1
(43) Pub. Date: Jun. 4, 2026

(54) SEMICONDUCTOR RING SURROUNDING VERTICAL DIODE AND RELATED METHODS

(71) Applicant: GlobalFoundries U.S. Inc., Malta, NY (US)

(72) Inventors: Steven M. Shank, Jericho, VT (US); Uppili S. Raghunathan, Essex Junction, VT (US); Aaron L. Vallett, Jericho, VT (US); Vibhor Jain, Clifton Park, NY (US)

(21) Appl. No.: 18/964,794

(22) Filed: Dec. 2, 2024

(51) Int. Cl. H01L 21/02

(52) U.S. Cl. CPC H10D 84/617; H10D 8/50; H10D 62/103

(57) ABSTRACT

The disclosure provides a semiconductor ring surrounding a vertical diode, and related methods. Structures according to the disclosure include a vertical diode over a substrate. A semiconductor ring is over the substrate and horizontally surrounds the vertical diode. A spacer material is horizontally adjacent the semiconductor ring and separates the semiconductor ring from the vertical diode.

### BACKGROUND

The present disclosure relates to bipolar transistor structures and methods to form such structures.

Present technology is at atomic level scaling of certain micro-devices such as logic gates, bipolar transistors, field effect transistors (FETs), and capacitors. Circuit chips with millions of such devices are common. Some circuits are implemented using diodes, i.e., junctions between a cathode and anode formed of semiconductor materials with opposite conductivity types. Diodes are electrical components that conduct current primarily in one direction across the junction. A PIN diode (alternately, “NIP” diode for the opposite polarity) refers to a diode structure in which a large intrinsic semiconductor material (i.e., semiconductor material with significantly less dopants therein) is between the cathode and anode. PIN diodes may be particularly suitable for use in switches, photodetectors, and/or high voltage applications. The presence of a large intrinsic semiconductor material in a PIN diode structure may make it difficult to integrate PIN diode processing with other front end of the line (FEOL) device processing.

### SUMMARY

The illustrative aspects of the present disclosure are designed to solve the problems herein described and/or other problems not discussed.

Embodiments of the disclosure provide a structure including: a vertical diode over a substrate; and a semiconductor ring over the substrate and horizontally surrounding the vertical diode, wherein a spacer material is horizontally adjacent the semiconductor ring and separates the semiconductor ring from the vertical diode.

Other embodiments of the disclosure provide a structure including: a PIN diode over a substrate, the PIN diode including: a cathode over the substrate and including a first conductivity type, an intrinsic semiconductor on a second portion of the cathode, and an anode on the intrinsic semiconductor and including a second conductivity type, wherein the semiconductor ring horizontally surrounds the anode; and a semiconductor ring over the cathode and horizontally surrounding the anode of the PIN diode, wherein a spacer material is horizontally adjacent the semiconductor ring and separates the semiconductor ring from the PIN diode, and wherein the semiconductor ring has the first conductivity type.

Additional embodiments of the disclosure provide a method including: forming a vertical diode over a substrate; and forming a semiconductor ring over the substrate and horizontally surrounding the vertical diode, wherein a spacer material is horizontally adjacent the semiconductor ring and separates the semiconductor ring from the vertical diode.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 depicts a cross-sectional view a structure according to embodiments of the disclosure.

FIG. 2 depicts a plan view of a structure according to embodiments of the disclosure.

FIG. 3 depicts a cross-sectional view a structure according to further embodiments of the disclosure.

FIG. 4 depicts a plan view of a structure according to further embodiments of the disclosure.

FIG. 5 depicts a cross-sectional view of a structure and bipolar transistor on one substrate according to embodiments of the disclosure.

FIGS. 6-10 depict cross-sectional views of processes in methods to form a structure according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

The disclosure provides a semiconductor ring surrounding a vertical diode, and related methods. Structures according to the disclosure include a vertical diode over a substrate. A semiconductor ring is over the substrate and horizontally surrounds the vertical diode. A spacer material is horizontally adjacent the semiconductor ring and separates the semiconductor ring from the vertical diode.

Diodes and related devices such as bipolar junction transistors (BJTs) in embodiments of the disclosure, operate using multiple “P-N junctions.” The term “P-N” refers to two adjacent materials having different types of conductivity (i.e., P-type and N-type), which may be induced through dopants within the adjacent material(s). A P-N junction, when formed in a device, may operate as a diode. A diode is a two-terminal element, which behaves differently from conductive or insulative materials between two points of electrical contact. Specifically, a diode provides high conductivity from one contact to the other in one voltage bias direction (i.e., the “forward” direction), but provides little to no conductivity in the opposite direction (i.e., the “reverse” direction). In the case of the P-N junction, the orientation of a diode's forward and reverse directions may be contingent on the type and magnitude of bias applied to the material composition of one or both terminals, which affects the size of the potential barrier. In the case of a junction between two semiconductor materials, the potential barrier will be formed along the interface between the two semiconductor materials. Generally, a BJT structure includes a base region vertically or horizontally between emitter and collector materials. A BJT can be either a PNP-type BJT or an NPN-type BJT. In a PNP-type BJT, the emitter and collector regions have P-type conductivity and at least a portion of the base region has N-type conductivity. In an NPN-type BJT, the emitter and collector regions have N-type conductivity and at least a portion of the base has P-type conductivity.

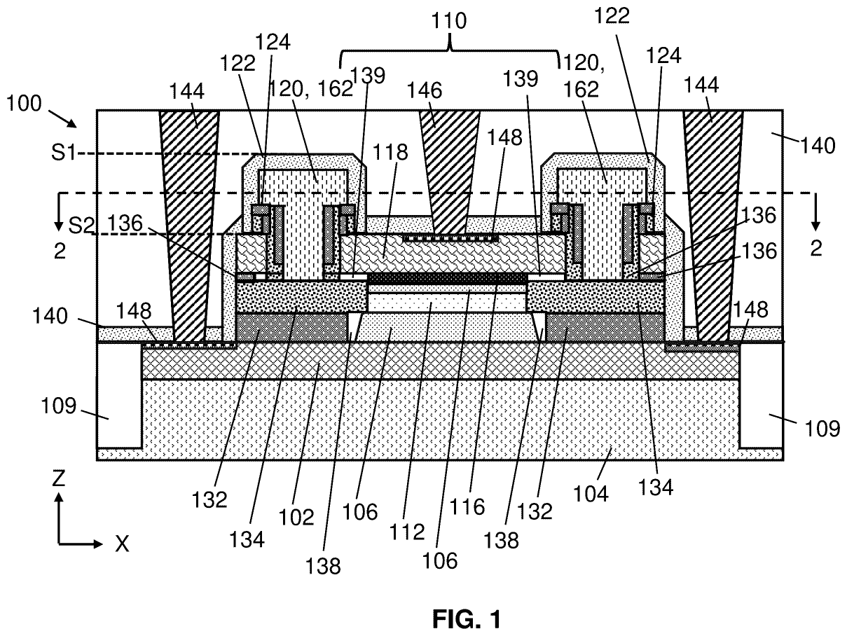

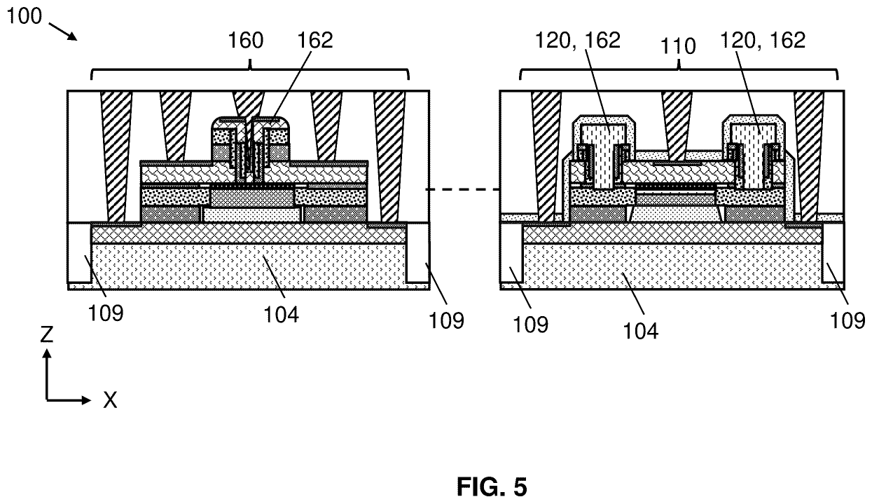

Referring to FIG. 1, a structure 100 according to the disclosure may include: a vertical diode (e.g., a “PIN” diode or alternately a “NIP” when implemented with opposite conductivity) 110 and adjacent semiconductor ring 120. Semiconductor ring 120 may laterally surround portions of vertical diode 110 to improve electrical isolation of vertical diode 110 from other structures and/or to enable processing integration of vertical diode 110 into other methodologies, e.g., those suitable to form BJTs. Semiconductor ring 120 may include a doped polycrystalline semiconductor 162 similar or identical to active material(s) within a bipolar transistor 160 (not shown in FIG. 1) elsewhere on substrate 104, e.g., by the arrangement shown in FIG. 5 and discussed elsewhere herein. Structure 100 may be formed on a cathode 102 (i.e., a portion of a semiconductor substrate 104 having a first conductivity type) including, e.g., one or more monocrystalline semiconductor materials. Cathode 102 may include but is not limited to silicon, germanium, silicon germanium (SiGe), silicon carbide, or any other common IC semiconductor substrates. Cathode 102 may be doped N-type, although it may be oppositely doped in other implementations. In the case of SiGe, the germanium concentration in cathode 102 may differ from other SiGe-based structures described herein. A portion or entirety of cathode 102 may be strained. Cathode 102 may be doped (i.e., it may define a “doped well”) , e.g., to enable coupling to overlying materials of vertical diode 110.

An intrinsic semiconductor 106 may be on cathode 102, e.g., as a single layer or multiple similarly doped but distinct layers formed by epitaxial deposition of silicon, SiGe, and/or other semiconductor materials on cathode 102 and may have a predetermined doping type, e.g., by being doped in-situ or during formation of semiconductor material(s) of cathode 102 and/or cathode 102. Intrinsic semiconductor 106 is monocrystalline in structure. Intrinsic semiconductor 106 may define some of the active semiconductor material within vertical diode 110, and more particularly, may be a portion of the intrinsic region between the cathode and anode terminals that are respectively P N-type doped and N P-type doped or vice versa. Intrinsic semiconductor 106 is illustrated as having sloped sidewalls over cathode 102. However, intrinsic semiconductor 106 may have other shapes (e.g., non-sloped sidewalls, curved sidewalls, etc.) as a result of varying manufacturing techniques.

Intrinsic semiconductor 106 may be compositionally distinct from other active portions of vertical diode 110, due to its comparatively low doping concentration. Intrinsic semiconductor 106 may be lightly doped either p-type or n-type regardless of whether vertical diode 110 is a PIN or NIP diode. Intrinsic semiconductor 106 in further implementations may be undoped, whereas active semiconductor materials above and below intrinsic semiconductor 106 may have different doping types and are doped more highly than intrinsic semiconductor 106. Despite the low doping or absence of dopants within intrinsic semiconductor 106, P-N junctions may form within vertical diode 110 due to the small height of intrinsic semiconductor 106 and substantially higher amounts of doping in active semiconductor materials in contact with upper and lower surfaces of intrinsic semiconductor 106.

Insulator 109, which optionally may be subdivided into multiple layers and/or materials of varying width and/or depth, may also be on cathode 102 to horizontally separate various active semiconductor materials on substrate 104. As shown, some insulators 109 may extend vertically into substrate 104, whereas others may be located on cathode 102 to prevent electrical shorting between cathode 102 and overlying areas of vertical diode 110. As discussed elsewhere herein insulator 109 initially may extend over substrate 104 as a single layer. Portions of insulator 109 may be removed to form a trench, which may undercut certain remaining portions of insulator 109 near cathode 102. The undercut portions of insulator 109 may form substantially triangular divots, recesses, etc., where intrinsic semiconductor 106 material may be grown. Thus, intrinsic semiconductor 106 when formed may have a tapered or sloped shape, as shown. In cases where intrinsic semiconductor 106 has tapered sidewalls, various materials on intrinsic semiconductor 106 (e.g., doped semiconductor 112 discussed herein) also may have tapered sidewall profiles, e.g., by selective epitaxial growth of additional material on intrinsic semiconductor 106.

Vertical diode 110 also may include an intermediate doped semiconductor 112 on intrinsic semiconductor 106. Intermediate doped semiconductor 112 may have the opposite conductivity type from cathode 102 thereunder, i.e., it may be doped p-type or n-type to a to approximately the same concentration as cathode 102, thus defining a P-N junction across intrinsic semiconductor 106. Intermediate doped semiconductor 112 also may differ from intrinsic semiconductor 106, e.g., by including silicon germanium (SiGe) where intrinsic semiconductor 106 includes Si. The sidewalls of intermediate doped semiconductor 112 also may be adjacent (e.g., in physical contact with) one or more dielectric materials, whereas intrinsic semiconductor 106 may be adjacent an air gap as discussed herein. In further implementations, intrinsic semiconductor 106 and intermediate doped semiconductor 112 may be upper and lower portions of one region having a substantially uniform composition of intrinsic semiconductor material(s). Optionally, as shown in FIG. 1, another layer of intrinsic semiconductor 106 material may be on intermediate doped semiconductor 112 such that intermediate doped semiconductor 112 is vertically between two regions of intrinsic semiconductor 106. In this case, intermediate doped semiconductor 112 may be a layer of doped SiGe (or other semiconductor) vertically between two layers of intrinsic semiconductor 106, which of which may include lightly doped or non-doped Si. In further implementations, all layers of intrinsic semiconductor 106 and intermediate doped semiconductor 112 may be replaced with one layer of intrinsic semiconductor 106, formed of Si and/or SiGe.

Vertical diode 110 also includes various doped semiconductor materials for defining the opposite terminal from cathode 102, but with varying compositions to enable forming a semiconductor ring 120 (discussed elsewhere herein), spacer material 122 alongside semiconductor ring 120, and other active devices (e.g., BJTs) elsewhere on substrate 104. Vertical diode 110 may include a semiconductor film 116 over intrinsic semiconductor 106 to enable deposition and growth of other semiconductor material(s) of different conductivity types thereon. Semiconductor film 116 may include, e.g., non-doped silicon (Si) in various crystalline forms, e.g., single crystallographic orientation Si, polycrystalline Si, etc. Semiconductor film 116 may be formed by forming intrinsic semiconductor 106 to a desired height before forming semiconductor film 116 thereon, and/or by removing a portion of intrinsic semiconductor 106 for replacement with semiconductor film 116. Semiconductor film 116 also may be formed by any other currently known or later developed technique to form transitional semiconductor material suitable for subsequent forming of an anode for vertical diode 110 thereon, having varying conductivity types and/or dopant concentrations.

Vertical diode 110 includes anode 118 on semiconductor film 116, above intrinsic semiconductor 106 (and intermediate doped semiconductor 112 therein where applicable) and above cathode 102. Anode 118 may include, e.g., polycrystalline Si or any other semiconductor material that is doped to have a predetermined polarity opposite that of cathode 102. Anode 118 may have a different crystallographic composition relative to cathode 102, in addition to having a different conductivity type. For instance, anode 118 may include polycrystalline Si in the case where cathode 102 includes monocrystalline Si. To provide a PIN diode structure, anode 118 may have p-type conductivity as compared to n-type conductivity in cathode 102. For a NIP diode structure, the positions of cathode 102 and anode 118 may be reversed. Regardless of conductivity type, anode 118 may have a doping concentration similar to that of cathode 102, and thus may have a substantially greater doping concentration than intrinsic semiconductor 106. However embodied, doped semiconductor anode 118 may extend to a predetermined height over semiconductor film 116. Anode 118 is illustrated with vertically extending sidewalls but may have sidewalls with a similar or different profile to intrinsic semiconductor 106 thereunder. Lower portions of anode 118 may define, e.g., a seed layer of polycrystalline semiconductor material(s) on which overlying portions of anode 118 are grown. Such portions of anode 118 are not separately identified in the accompanying FIGS. for clarity of illustration.

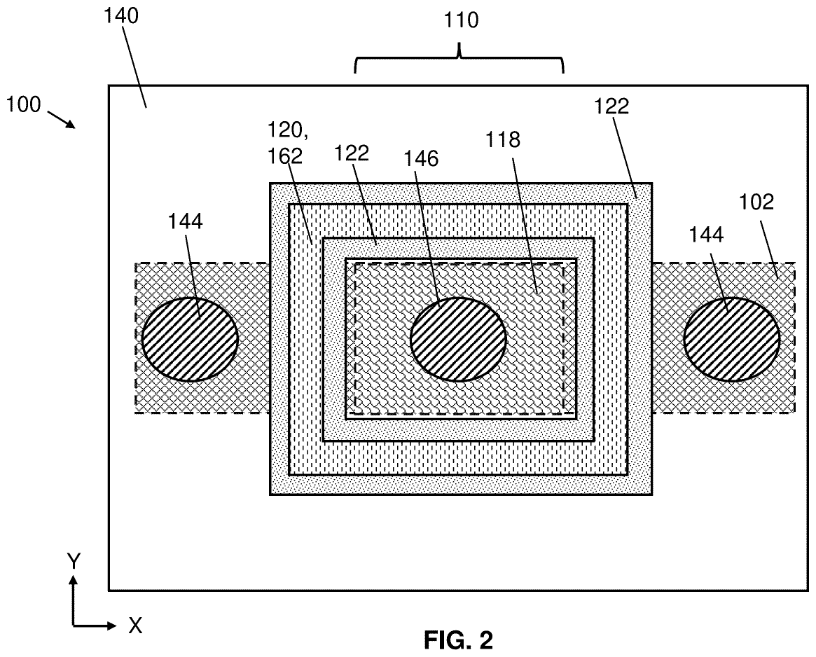

Referring to FIGS. 1 and 2 together, with FIG. 2 providing a plan view along view line 2-2 of FIG. 1, structure 100 may include a semiconductor ring 120 over substrate 104 (FIG. 1 only) and horizontally surrounding vertical diode 110, including anode 118 thereof. Two portions of semiconductor ring 120 are shown in FIG. 1, and as indicated in FIG. 2 semiconductor ring may horizontally surround vertical diode 110 such that semiconductor ring 120 defines a looping shape. Semiconductor ring 120 may include any currently known or later developed semiconductor material, and as an example may include crystalline Si with any conceivable doping profile. In some cases, semiconductor ring 120 may have a similar or identical composition and doping profile to emitter terminals located elsewhere in a device. Such properties may arise, e.g., from forming semiconductor ring 120 simultaneously with emitter terminals for bipolar transistors in other locations. Semiconductor ring 120, in the example of FIG. 2, is substantially rounded but other shapes (e.g., rectangles, triangles, and/or any number of features defining a looping horizontal boundary about vertical diode 110) also may be considered a “ring” in embodiments of the disclosure. Regardless of geometry, semiconductor ring 120 is structured to horizontally surround vertical diode 110, and thus horizontally separates anode 118 and underlying active materials of vertical diode 110 from other materials located outside semiconductor ring 120. Semiconductor ring 120 may be formed simultaneously with bipolar transistors located elsewhere on substrate 104 (FIG. 1), and/or may be formed by adapting processes similar or identical to those implemented to form bipolar transistors. Semiconductor ring 120, when formed similarly to and/or simultaneously with the emitter(s) of bipolar transistor(s) on substrate 104, may extend vertically above anode 118 such that an upper surface S1 of semiconductor ring 120 is above an upper surface S2 of anode 118.

A spacer material 122 may be located horizontally on sidewalls of semiconductor ring 120, such that spacer material 122 also horizontally surrounds vertical diode 110. Spacer material 122 thus may be horizontally adjacent the horizontal interior and exterior of semiconductor ring 120, thereby separating semiconductor ring 120 from vertical diode 110. Spacer material 122 may be any currently known or later developed dielectric substance. As examples, spacer material 122 may be a nitride based insulator formed alongside semiconductor ring 120, or alternatively, an oxide based insulator formed adjacent semiconductor ring 120. Optionally, alternative configurations of spacer material 122 may include multiple distinct layers of dielectric substances formed (e.g., as discussed in various examples of processing herein) to provide a particular arrangement of insulative materials surrounding vertical diode 110. Other compositions and/or arrangements of spacer materials 122 currently known or later developed also may be used. To enable differences in processing of spacer material 122 relative to surrounding structures, spacer material(s) 122 may have compositions different from insulator 109 or other insulating structures.

Semiconductor ring 120 also may include, e.g., inner spacers 124 alongside spacer material 122 and anode 118. Inner spacer(s) 124 may be formed separately from spacer material(s) 122 during processing, e.g., to provide electrical separation between semiconductor ring 120 and adjacent active material in anode 118. Inner spacer(s) 124 may include various oxide and/or nitride insulators and may include similar or different materials relative to spacer material(s) 122. Inner spacer(s) 124 may be considered to be part of spacer material(s) 122, notwithstanding any differences in composition. Inner spacer(s) 124, further, are shown with multiple forms of cross-hatching to indicate that they may include multiple layers having different compositions. In some implementations, inner spacer(s) 124 and spacer material(s) 122 may have a substantially uniform composition.

Referring to FIG. 1, semiconductor ring 120 may be separated from cathode 102 thereunder by additional insulative materials, thus further vertically isolating semiconductor ring 120 from active semiconductor materials in vertical diode 110. Specifically, structure 100 includes a first isolation layer 132 on portions of cathode 102 that do not have intrinsic semiconductor 106 thereover. A second isolation layer 134 can also be on first isolation layer 132, and a third isolation layer 136 also can be on second isolation layer 134. In such configurations, a first air gap 138 can be between first isolation layer 132 and intrinsic semiconductor 106, and a second air gap 139 between third isolation layer 136 and semiconductor film 116. Isolation layers 132, 134, 136 may extend above cathode 102 to approximately the same combined height as intrinsic semiconductor(s) 106, doped semiconductor 112, and semiconductor film 116. The shape and position of isolation layers 132, 134, 136 may be effective for allowing anode 118 to be formed on semiconductor film 116 and above third isolation layer 136 simultaneously.

First isolation layer 132 may include, e.g., a first dielectric material such as an oxide-based insulator (e.g., silicon dioxide (SiO₂)), or other materials having similar properties. First isolation layer 132 may have the same composition as insulator 109 discussed herein, but this is not necessarily required and thus first isolation layer 132 is shown with different cross-hatching from insulator 109 where applicable. First isolation layer 132 may be formed, e.g., by deposition of desired material(s) on cathode 102, insulator 109, etc. First isolation layer 132 may not abut doped semiconductor 112 due to earlier etch of an opening in first isolation layer 132 before intrinsic semiconductor 106 is formed in that opening and before doped semiconductor 112 is formed on intrinsic semiconductor 106, according to processes discussed herein.

Second isolation layer 134 may include, e.g., a nitride-based insulator such as silicon nitride (SiN). Second isolation layer 134 may have a different composition from first isolation layer 132, e.g., second isolation layer 134 may be nitride-based, whereas, as mentioned above, first isolation layer 132 may be oxide-based or vice versa. Second isolation layer 134 may extend horizontally over first isolation layer 132, and over air gap 138 (e.g., over an outer edge of intrinsic semiconductor 106), such that a sidewall of second isolation layer 134 horizontally abuts a portion of doped semiconductor 112. In some cases, second isolation layer 134 may only horizontally abut a lower portion of doped semiconductor 112 (e.g., areas below semiconductor film 116 and thus beneath air gap 139). Second isolation layer 134 initially may be formed as a continuous layer over first isolation layer 132, before portions of each layer 132, 134 are removed to enable forming of intrinsic semiconductor 106 and doped semiconductor 112 thereon, as discussed in various examples herein.

Third isolation layer 136 on second isolation layer 134 also may be horizontally adjacent second air gap 139, such that second air gap 139 is horizontally between third isolation layer 136 and semiconductor film 116. A portion of anode 118 may be over third isolation layer 136 and optionally may overlap third isolation layer 136. Third isolation layer 136, in some cases, may have the same composition as first isolation layer 132. For example, isolation layers 132, 136 both may be oxide-based materials such as SiO₂ or any other currently known or later developed oxide-based insulator(s). In a further example, layers 132, 134, 136 together may define an oxide-nitride-oxide (ONO) configuration over cathode 102 and insulator(s) 109. In alternative configurations, only one or two of layers 132, 134, 136 may be present, e.g., an upper portion of second layer 134 may extend into the location of third isolation layer 136 when third isolation layer 136 is not present. Although layers 132, 134, 136 of isolation stack may have a substantially aligned sidewall over cathode 102 distal to doped semiconductor 112, their sidewalls proximal to doped semiconductor 112 may not be aligned due to air gaps 138, 139. These and other aspects may be due to processing techniques implemented to form each layer 132, 134, 136 of isolation stack, and also may be attributable to the forming of intrinsic semiconductor 106, doped semiconductor 112, and semiconductor film 116 as discussed herein. In any case, the position and shape of air gaps 138, 139 may, beneficially, further isolate intrinsic semiconductor 106, portions of doped semiconductor 112, and/or other materials from certain components.

FIG. 1 also illustrates air gaps 138, 139. The term “air gap,” as used herein, refers to a region of space surrounded by (and hence not filled with) solid materials such as insulator 109, any of isolation layers 132, 134, 136, etc. Air gaps 138, 139, alternatively known as a “cavity,” “gas dielectric,” and/or similar terms known in the art, thus may have a lower dielectric constant (i.e., it is less conductive) than nearby insulative materials such layers 132, 134, 136. Air gap 138, 139 thus may be formed by any currently known or later developed process to create an insulative region of space not filled with dielectric materials and/or other components, and various examples are provided herein.

Air gaps 138, 139 may be formed by any conceivable method to enclose and/or seal off a desired space to prevent additional materials from being formed therein. For instance, the forming and shaping of layers 132, 134 may include removing a portion of second isolation layer 134 and first isolation layer 132 thereunder such that a remaining portion of second isolation layer 134 overhangs empty space previously occupied by a region of first isolation layer 132. By forming intrinsic semiconductor 106 on cathode 102 in the area previously occupied by a portion of first isolation layer 132 by epitaxial growth and deposition, or similar techniques, the newly formed intrinsic semiconductor 106 material will not propagate horizontally. When the forming of intrinsic semiconductor 106 concludes, vacant space will remain between intrinsic semiconductor 106 and first isolation layer 132 to define at least a portion of first air gap 138.

First air gap 138 may extend alongside intrinsic semiconductor 106 and thus may have a similar shape to the adjacent portion(s) of intrinsic semiconductor 106. To affect the eventual shape of air gap 138, the forming of intrinsic semiconductor 106 may be controlled such that its upper surface is below the lower surface of second isolation layer 134. Techniques effective to produce this difference in height may include, e.g., terminating the forming of intrinsic semiconductor 106 after a certain amount of time, removing portions of intrinsic semiconductor 106 after it is formed to create a desired size, and/or various other combinations of currently known or later developed processes. Subsequent forming of doped semiconductor 112 (e.g., by vertical deposition) on intrinsic semiconductor 106 may inhibit horizontal propagation of additional semiconductor material to define the shape of first air gaps 138. It is thus understood that first air gaps 138 can have any number of other shapes by further modifying the process(es) to form intrinsic semiconductor 106, doped semiconductor 112, isolation layers 132, 134, 136, etc. Each first air gap 138 may be one of a pair of first air gaps 138, each horizontally adjacent a respective sidewall of intrinsic semiconductor 106.

In structure 100, second isolation layer 134 is horizontally adjacent a portion (e.g., a lower and/or middle portion) of doped semiconductor 112 such that the interface between doped semiconductor 112 and isolation layer(s) 132, 134, 136 partially defines a boundary of first air gap 138. Second air gap 139 also may be over second isolation layer 134. Second air gap 139 may be an area of space horizontally between an upper portion of doped semiconductor 112 (e.g., having semiconductor film 116) and third isolation layer 136. Second air gap 139 may be created from different phases and/or techniques in processing from those operable to form first air gap 138. For instance, to form second air gap 139, a portion of third isolation layer 136 material may be removed, e.g., by etching, to expose doped semiconductor 112 and second isolation layer 134 thereunder. Subsequent processing may include forming semiconductor film 116 such that doped semiconductor 112 has a desired height (e.g., to have an upper surface substantially coplanar with the upper surface of third isolation layer 136).

The forming of semiconductor film 116 may not cause additional semiconductor material to propagate into empty space over second isolation layer 134, e.g., where semiconductor film 116 is formed by deposition. Second air gap(s) 139 may have a substantially rectangular shape with a height essentially equal to the height of third isolation layer 136, e.g., where second isolation layer 134 has a substantially flat upper surface and where the adjacent portion of third isolation layer 136 has substantially vertical sidewalls. Second air gap 139 optionally may take on different shapes, depending on the shape of isolation layer(s) 132, 134, 136 and doped semiconductor 112. Doped semiconductor 112 on intrinsic semiconductor 106 also may include a sloped sidewall adjacent and/or below second air gap 139, e.g., in cases where doped semiconductor 112 is formed by epitaxial growth or otherwise formed selectively on intrinsic semiconductor 106. Semiconductor film 116 also may extend horizontally over a portion of second isolation layer 134 such that the size and profile of second air gap 139 varies with the size and shape of semiconductor film 116. Second air gap 139 may be provided as a pair of second air gaps 139, each horizontally adjacent a respective sidewall of doped semiconductor 112 (e.g., alongside semiconductor film 116 thereof).

Each air gap 138, 139 may span horizontally between active material of vertical diode 110 and isolation layers 132, 134, 136. Second isolation layer 134 may vertically separate air gaps 138, 139 from each other. Overlying portions of anode 118 may define the upper boundary of second air gap 139. First air gap 138 and second air gap 139 may have different shapes due to differences in the shape, size, and/or composition of adjacent materials defining each air gap 138, 139. Each air gap 138, 139, however shaped, may increase the electrical insulation between intrinsic semiconductor 106, doped semiconductor 112, anode 118, and any interconnected parts of vertical diode 110 from other conductive or semiconductive materials in structure 100. Air gaps 138, 139 may be desirable as further contributing to the electrical isolation provided by isolation layers 132, 134, 136. Air gaps 138, 139 in particular may impede or prevent other physical interfaces from forming between vertical diode 110 and other materials, except where desired as discussed herein.

Structure 100 may include an inter-level dielectric (ILD) layer 140 over insulator 109, vertical diode 110, semiconductor ring 120, etc. ILD layer 140 may include the same insulating material as insulator 109 or may include a different electrically insulative material for vertically separating active materials from overlying materials, e.g., various horizontally extending wires or vias. ILD layer 140 and insulator 109 nonetheless constitute different components, e.g., due to insulator 109 being horizontally between cathode 102 and various other active components of structure 100. ILD layer 140 may be formed by deposition and/or other techniques to provide electrically insulating materials, and can then be planarized (e.g., using CMP), such that its upper surface remains above any active components formed over cathode 102 and/or substrate 104.

One or more cathode contacts 144 through ILD layer 140 may provide the vertical electrical coupling to cathode 102 from overlying metal wires and/or vias. Two cathode contacts 144 to cathode 102 are shown, but any desired number of cathode contacts 144 may be present in structure 100. Structure 100 also includes an anode contact 146 extending through ILD 140 to anode 118. Although one anode contact 146 is shown, any desired number of anode contacts 146 may be present, and further implementations discussed herein include additional anode contacts 146 to anode(s) 118 of vertical diode 110. Notably, structure 100 does not include any contact(s) to semiconductor ring 120. Thus, semiconductor ring 120 remains electrically inactive during operation of a device. Some portions of cathode 102 and anode 118 may be converted into a silicide layer 148 to improve conductivity between each contact 144, 146 and any semiconductor material(s) thereunder, e.g., by providing a conductive metal such as cobalt (Co), titanium (Ti), nickel (Ni), platinum (Pt), or similar material on the upper surface(s) of a targeted material. The conductive material(s) may be annealed while in contact with the underlying semiconductor to produce silicide layer 148 for electrically coupling semiconductor materials to any contacts formed thereon. Excess conductive material can then be removed using any now known or later developed solution, e.g., etching.

Each contact 144, 146 may extend through ILD layer 140, thus electrically connecting active semiconductor material within cathode 102 or anode 118 to overlying metal wires, vias, etc., above structure 100. Contact(s) 144, 146 optionally may be formed as part of a single operation, e.g., by removing portions of ILD layer 140 to form openings, forming silicide layers 148 on semiconductor materials exposed within the openings, and filling the openings with metal to define each contact 144, 146. One or more of contacts 144, 146 may include refractory metal liners (not separately shown) on their sidewalls to impede or prevent electromigration degradation, shorting to other components, etc.

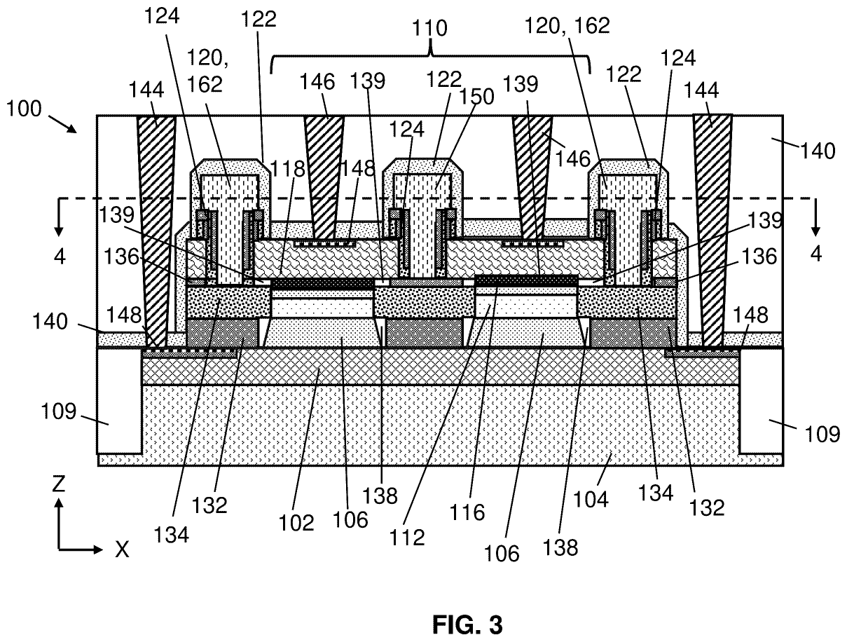

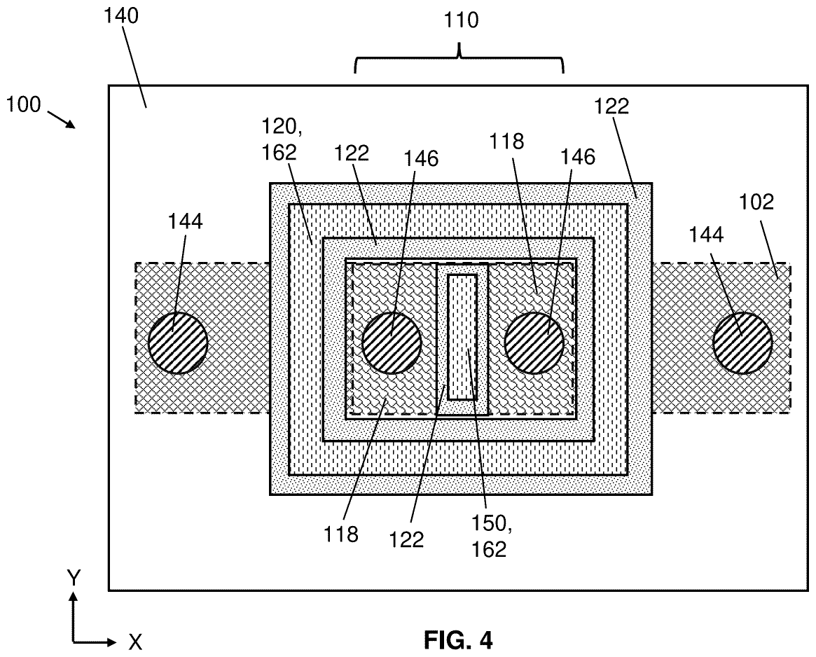

Turning to FIGS. 3 and 4, further implementations of structure 100 may include a semiconductor pillar 150 horizontally between multiple anode contacts 146, such that anode contacts 146 are horizontally between semiconductor pillar 150 and semiconductor ring 120. Semiconductor pillar, similar to semiconductor ring 120, may have spacer material 122 (and inner spacer(s) 124 where applicable) alongside its sidewalls, and may be free of conductive contacts thereto. Semiconductor pillar 150 may differ from semiconductor ring 120 by not having a looping structure, i.e., it does not feature a horizontally hollow interior. Semiconductor pillar 150, during operation, may electrically isolate multiple anode contacts 146 and/or portions of anode 118 from each other to provide multiple cathode-diode pathways within vertical diode 110. As shown, semiconductor pillar 150 and its spacer(s) 122, 124 may extend vertically to isolation layer(s) 136 to separate certain portions of anode 118 from each other. Although anode 118 is shown to be discontinuous in FIG. 4, this is not necessarily required (e.g., semiconductor pillar 150 may not extend completely horizontally across anode 118).

Anode contacts 146 and cathode contacts 144 may electrically couple vertical diode 110 to different metal wires and/or vias to implement a larger variety of circuit configurations. Although two anode contacts 146 and one semiconductor pillar 150 are shown in FIGS. 3 and 4 as an example, any number of anode contacts 146 and/or semiconductor pillars 150 may be provided in other configurations. In any case, semiconductor ring 120 may horizontally surround all anode contacts 146 and/or semiconductor pillars 150 in structure 100 to isolate these components from cathode contact(s) 144, as well as any active materials and/or components located outside structure 100. In all other respects, structure 100, vertical diode 110, and/or semiconductor ring 120 may be similar or identical to other implementations discussed herein.

Turning now to FIG. 5 in reference to FIG. 1, embodiments of structure 100 may allow vertical diode 110 to be implemented on substrate 104 together with any desired number of bipolar transistors 160. Two portions of substrate 104 surrounded by respective insulators 109 may be on different portions of a device. A dashed line is shown in FIG. 5 to show an indeterminate distance between vertical diode 110 and bipolar transistor 160 (i.e., they may be directly adjacent each other or separated by any conceivable distance despite being on one substrate 104). The subcomponents of vertical diode 110 and bipolar transistor 160 are not separately labeled for clarity of illustration.

As shown, bipolar transistor 160 may include a similar number of layers over substrate 104 and/or composition within each layer as vertical diode 110. The structure and composition of vertical diode 110 and semiconductor ring 120 may enable these components to be formed simultaneously with bipolar transistor(s) 160 in a single processing methodology. In addition, bipolar transistor 160 and vertical diode 110 each may include a doped polycrystalline semiconductor 162 therein. Bipolar transistor 160 may include doped polycrystalline semiconductor 162 within its emitter terminal, and vertical diode 110 may include doped polycrystalline semiconductor 162 within its semiconductor ring 162. The same material(s) being present in semiconductor ring 120 and bipolar transistor 160, and in the same layers, indicates that semiconductor ring 120 and bipolar transistor 160 are formed together in structure 100. Although not separately shown in FIG. 5, structure 100 also may be implemented with semiconductor pillar 150 (FIGS. 3, 4) and multiple anode contact(s) 146 (FIGS. 3, 4) with bipolar transistor 160 on substrate 104 in a similar configuration.

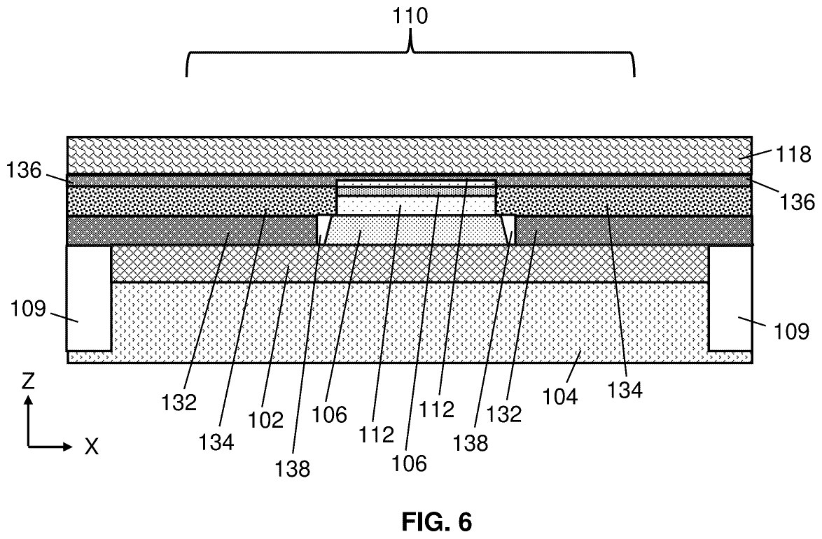

Turning to FIG. 6, the disclosure provides methods to form structure 100. Initial processing to form structure 100 may include forming vertical diode 110 over substrate 104. Initial phases of processing may include forming cathode 102 on substrate 104 (e.g., by targeted doping of semiconductor material to desired concentrations), forming insulator(s) 109 and/or other isolating materials adjacent cathode 102 and substrate 104, etc. Further processing may include forming first isolation layer 132 on cathode 102 and insulator(s) 109 and second isolation layer 134 on first isolation layer 132, e.g., by forming two layers of insulating material by deposition or other currently known or later developed techniques to provide insulator materials. As discussed herein, first isolation layer 132 may be oxide based and second isolation layer 134 may be nitride based (or vice versa), but various other compositions are possible.

Methods of the disclosure may include removing a portion of isolation layers 132, 134, e.g., via one or more forms of etching. The removing of isolation layers 132, 134 may terminate at the upper surface of cathode 102 for instance by controlling the etch time and/or by using any currently known or later developed selective etchants operable to remove layers 132, 134 material(s) without significantly removing or otherwise affecting semiconductor materials (e.g., cathode 102). Where applicable, etching may be implemented in multiple phases and with multiple etchants such that the width between remaining parts of first isolation layer 132 is larger than the width between remaining parts of second isolation layer 134. Such etching may undercut a portion of second isolation layer 134 to enable first gap(s) 138 to be defined when forming intrinsic semiconductor 106 and doped semiconductor 112 of vertical diode 110 alongside isolation layers 132, 134. For example, in some embodiments, portions of second isolation layer 134 using lithographic patterning and anisotropic etch techniques. In this case, the anisotropic etch can be selective for the material of the second isolation layer 134 so that it stops at first isolation layer 132. Then, a lower portion of the opening can be formed in first isolation layer 132 using an isotropic etch process. In this case, the isotropic etch process can be selective for first isolation layer 132 so that it stops at cathode 102 and also so that it undercuts second isolation layer 134 (i.e., so the lower portion is wider than the upper portion).

Continued processing in methods of the disclosure may include forming intrinsic semiconductor 106 in the wider, lower space between remaining portions of first isolation layer 132, and doped semiconductor 112 on intrinsic semiconductor 106 in the narrower upper space between remaining portions of second isolation layer 134. Forming of intrinsic semiconductor 106 and doped semiconductor 112 may be implemented by selective epitaxial growth and/or doping of semiconductor materials between first isolation layer 132. As shown, such processing may include forming intrinsic semiconductor 106 on cathode 102, in which intrinsic semiconductor 106 and cathode 102 have a same doping type but intrinsic semiconductor 106 has a lower doping concentration. In the case of forming by epitaxial growth, intrinsic semiconductor 106 may have sidewall shapes dependent on the manner of growth implemented and/or the crystallographic orientation of cathode 102 thereunder. The forming of intrinsic semiconductor 106, e.g., by epitaxial growth and deposition, defines first air gaps 138. In this case, intrinsic semiconductor 106 may not completely horizontally fill the space between remaining portions of first isolation layer 132.

Further processing may include, e.g., forming doped semiconductor 112 (e.g., doped SiGe as discussed herein) on intrinsic semiconductor 106. Doped semiconductor 112 may have an opposite doping type than cathode 102, and in addition, may have a lower concentration of dopants therein. Doped semiconductor 112 may be doped through implantation and/or other currently known or later developed doping techniques. The forming of doped semiconductor 112 may begin only after intrinsic semiconductor 106 is at or near the height of first isolation layer 132 above cathode 102. In this case, doped semiconductor 112 once formed will horizontally abut second isolation layer 134 but will not fill vacant space alongside intrinsic semiconductor 106. As a result, first air gaps 138 are defined between intrinsic semiconductor 106 and first isolation layer 132. As discussed herein, first air gaps 138 may be adjacent to a sidewall of intrinsic semiconductor 106 and, optionally, may extend over sidewalls of intrinsic semiconductor 106 as a result of the various process(es) selected to form layers 132, 134, intrinsic semiconductor 106, and/or doped semiconductor 112. Further processing may include, e.g., ceasing further deposition of doped semiconductor 112 to form additional portions of intrinsic semiconductor 106 as non-doped or lightly doped additional semiconductor material, and thereafter continuing to form doped semiconductor 112. Among other things, alternating additional intrinsic semiconductor 106 material with additional doped semiconductor 112 may be operable to reduce or prevent dopant migration form one terminal of vertical bipolar transistor 110 to the other in subsequent processing phases.

Third isolation layer 136 can be formed on second isolation layer 134 by additional deposition of insulative material (e.g., oxide based insulators as discussed herein) on second isolation layer 134. Initially, third isolation layer 136 also covers doped semiconductor 112 and thus extends continuously over doped semiconductor 112 from one portion of second isolation layer 134 to another. Anode 118 (e.g., doped polycrystalline semiconductor materials) can be formed as a single layer on third isolation layer 136 to a desired height. The forming of anode 118 may include first depositing a seed layer of semiconductor material on third isolation layer 136 and thereafter epitaxially growing additional semiconductor material to form anode 118. Anode 118 is located over intrinsic semiconductor(s) 106 and doped semiconductor(s) 112, but portions of anode 118 also may be over isolation layers 132, 134, 136. Initial processing of the structure, thereafter, may include forming a precursor spacer 170 (e.g., any insulative spacer material such an oxide-based spacer or nitride-based spacer) as a single layer to a desired height. Precursor spacer 170 may be used and processed in further stages to enable the forming of semiconductor ring 120 (FIGS. 1-5) in desired locations.

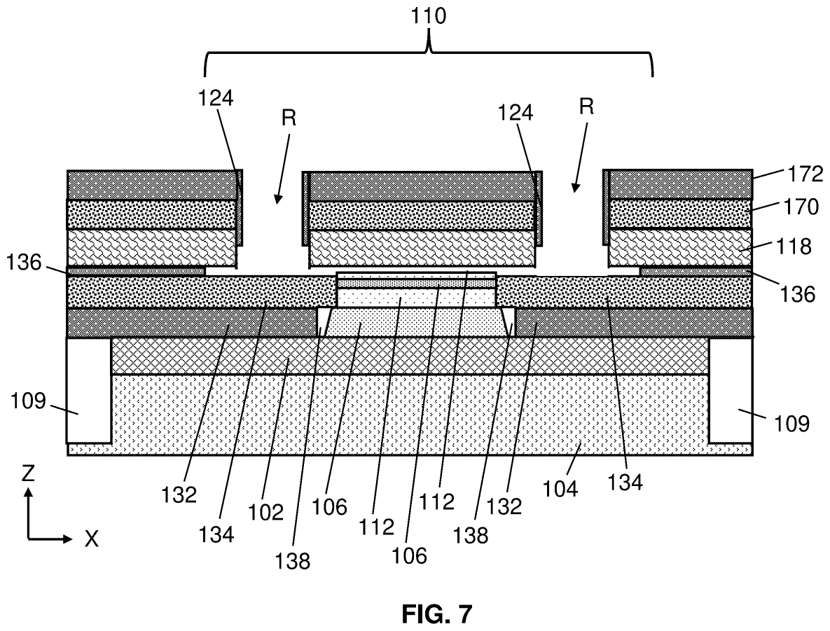

Turning to FIG. 7, methods of the disclosure may include forming a spacer mask 172 on precursor spacer 170. Spacer mask 172 may include any currently known or later developed material suitable for masking of underlying layers for processing via etching. For example, spacer mask 172 may be a nitride-based insulator in the case where precursor spacer is oxide-based, or vice versa Spacer mask 172 may include openings shaped to horizontally surround the previously formed stack of active materials on cathode 102 (e.g., intrinsic semiconductor 106, doped semiconductor 112, etc.). Continued processing may include forming openings R within third isolation layer 136, anode 118, and precursor spacer 170. Openings R initially may be within spacer mask 172 and not underlying materials. With spacer mask 172 in place, underlying portions of precursor spacer 170, and optionally a portion of anode 118, can be removed. Additional spacer material(s) then can be formed on the sidewalls of the partially etched openings R to create inner spacer(s) 124 (e.g., additional insulative materials discussed herein) via conformal deposition or other techniques to form spacer material(s). Continued etching of anode 118 and third isolation layer 136 may be implemented, e.g., by selective or non-selective etching to re-expose underlying portions of second isolation layer 134 within each opening R. Such etching may completely remove a portion of third isolation layer 136 over intrinsic semiconductor 106 and doped semiconductor 112. Although portions of anode 118, precursor spacer 170, and spacer mask 172 appear to be floating in the cross-section of FIG. 7, this is because these material(s) extend into and out of the plane of the page to reconnect with non-removed materials and thus define a bridge structure over semiconductors 106, 112.

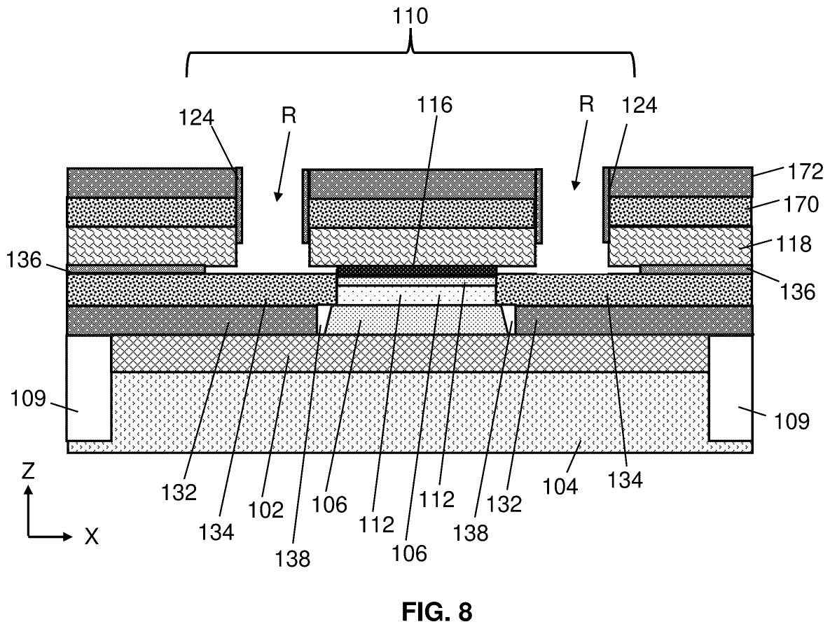

Turning to FIG. 8, further processing may include selective forming of semiconductor film 116 (e.g., a layer of semiconductor material, doped during growth or after growth in situ to have the same conductivity as doped semiconductor 112) with a different composition and/or crystallographic orientation on doped semiconductor 112. To prevent semiconductor film 116 from being formed in locations other than vertically between doped semiconductor 112 and anode 118, inner spacer(s) 124 initially may be formed on the entire sidewall of anode 118 (e.g., to prevent other semiconductor material(s) from being exposed in opening(s) R. Semiconductor film 116 then can be formed selectively such that its upper surface contacts the lower surface of anode 118, and some portions of inner spacer(s) 125 then may be removed (e.g., by partial selective etch) to re-expose sidewall surfaces of anode 118. Semiconductor film 116 may be doped by any conceivable process, e.g., by thermal anneal after semiconductor film 116 is formed. Semiconductor film 116 being formed by selective deposition (e.g., epitaxial growth and doping on the composition doped semiconductor 112) prevents semiconductor film 116 from being formed on other semiconductor materials (e.g., anode 118) within opening R.

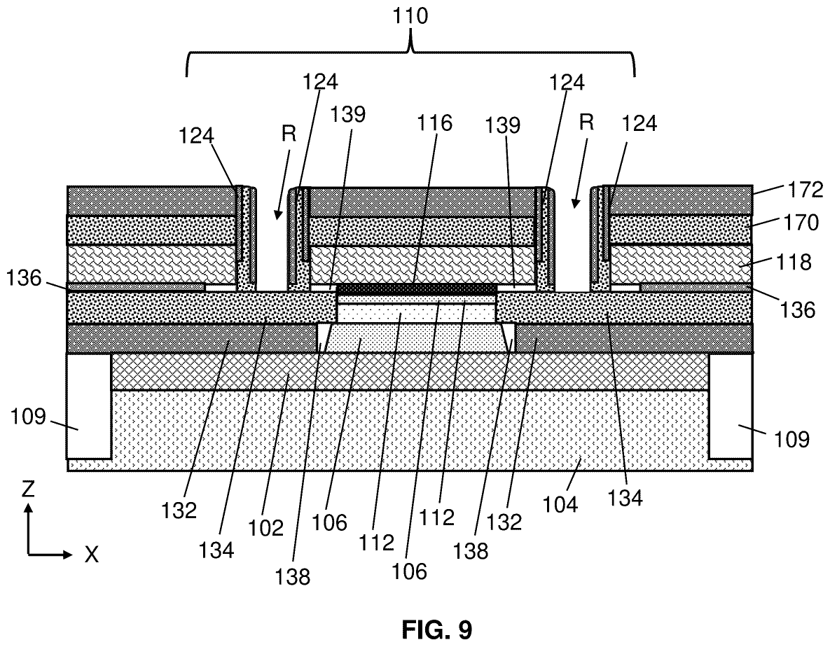

FIG. 9 depicts further processing to form remaining portions of inner spacer(s) 124 on the sidewalls of openings R. Inner spacers 124 each may include additional insulative spacer material formed conformally on anode 118, precursor spacer 170, and spacer mask 172 within opening(s) R. After forming inner spacer(s) 124, any portions of spacer material also formed at the bottom of opening(s) R may be removed by non-selective directional etching such that second isolation layer 134 remains exposed within openings R. The forming of inner spacers 124 within openings R also may define air gaps 139 horizontally between semiconductor film 116 and inner spacers 124, e.g., in cases where the remaining space between second isolation layer 134 and anode 118 is too small for deposited spacer material to enter.

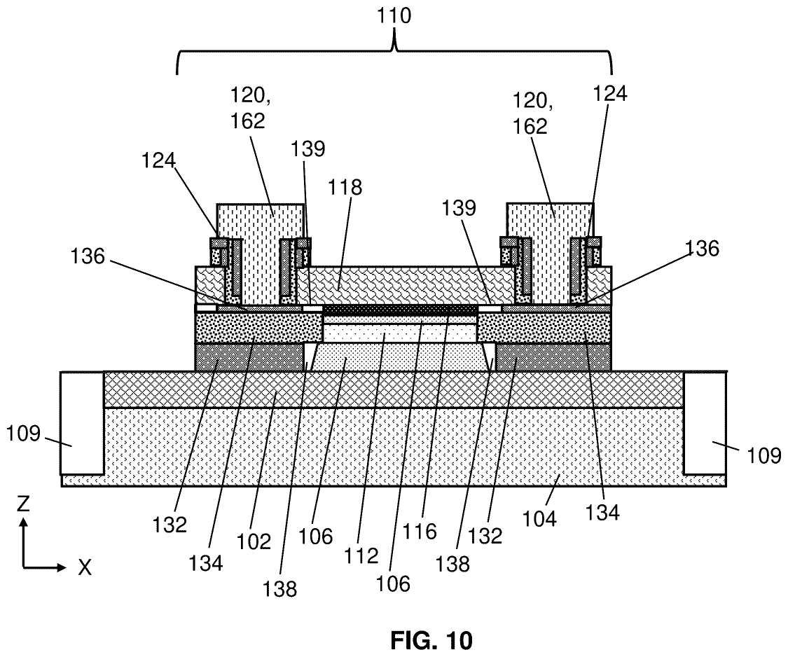

FIG. 10 depicts further processing to form semiconductor ring 120 around vertical diode 110. After inner spacers 124 are formed within openings R (FIGS. 7-9), further methods of the disclosure may include removing portions of anode 118, precursor spacer 170, and spacer mask 172 outside vertical diode 110, in addition to portions of isolation layers 132, 134, 136 located away from vertical diode 110 by a threshold distance. Such removing can be implemented by forming a temporary mask (not shown) on desired areas and removing any material(s) above substrate 104 not covered by the temporary mask. Optionally, additional inner spacer 124 material may be formed by additional conformal deposition of insulative material on portions of inner spacer 124 located on anode 118. Thereafter, semiconductor ring 120 may be formed by depositing semiconductor material to fill openings R, with additional portions of semiconductor material optionally extending over adjacent portions of inner spacers 124. Semiconductor ring 120, although shown in two locations in FIG. 10, may have a looped or other “ring” shaped structure by being formed within space defined to create a looping pattern, e.g., as shown by example in the X-Y plane views of FIGS. 2 and 4. Semiconductor ring 120 may at least partially include doped polycrystalline semiconductor 162 having a same or similar composition to an emitter terminal of a conventional bipolar transistor. In some implementations, semiconductor ring 120 may be formed during the same instance(s) of deposition to form bipolar transistor(s) 160 (FIG. 5) elsewhere over substrate 104.

After being formed, semiconductor ring 120 may horizontally surround cathode 102, semiconductors 106, 112, and anode 118 of vertical diode 110. Subsequent processing may include, e.g., forming spacer material(s) 122 on vertical diode 110 using conformal deposition to cover semiconductor ring 120 and exposed active materials (e.g., anode 118) of vertical diode 110. Additional processing includes forming ILD 140 (FIG. 1) over vertical diode 110 and semiconductor ring 120, forming openings within ILD 140, creating silicide regions 148 in the formed openings, and forming contact(s) 144, 146 within ILD 140 to create structure 100 as shown in FIG. 1. As discussed herein, semiconductor ring 120 may be free of contact(s) 144, 146 thereto and may electrically isolate surrounded portions of anode 118 from outer areas of cathode 102 and/or from other active components on substrate 104.

Embodiments of the disclosure provide various technical and commercial advantages, examples of which are discussed herein. Embodiments of the disclosure are operable to form vertical diode 110 without requiring different mask levels and/or processing steps from those used to form bipolar transistor(s) 160 (FIG. 6) elsewhere on the same substrate 104. In addition, the implementation of such processing techniques to create vertical diode 110 yields various operational benefits. For example, the use of isolation layer(s) 132, 134, 136 and the combination of intermediate doped semiconductor 112 with intrinsic semiconductor(s) 106 helps to reduce diffusion of dopants from cathode 102 or anode 118 into the intrinsic semiconductor material(s) therebetween as the structure is formed. During operation, this may allow vertical diode 110 to achieve lower amounts of parasitic capacitance and/or higher amounts of breakdown current or voltage.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a vertical diode over a substrate; and
a semiconductor ring over the substrate and horizontally surrounding the vertical diode, wherein a spacer material is horizontally adjacent the semiconductor ring and separates the semiconductor ring from the vertical diode.

2. The structure of claim 1, further comprising an isolation layer vertically between a cathode of the vertical diode and the semiconductor ring, wherein the isolation layer is below an anode of the vertical diode.

3. The structure of claim 1, wherein the semiconductor ring is free of conductive contacts thereto.

4. The structure of claim 1, further comprising a bipolar transistor (BT) over the substrate and distal to the vertical diode, wherein an emitter of the BT and the semiconductor ring each include a doped polycrystalline semiconductor.

5. The structure of claim 1, wherein the vertical diode includes:
a first terminal over the substrate and including a first conductivity type, wherein a first portion of the cathode is below the semiconductor ring;
an intrinsic semiconductor on a second portion of the first terminal; and
second terminal on the intrinsic semiconductor and including a second conductivity type, wherein the semiconductor ring horizontally surrounds the anode.

6. The structure of claim 1, further comprising a semiconductor pillar over the substrate and adjacent the vertical diode, wherein the semiconductor ring surrounds the vertical diode and the semiconductor pillar.

7. The structure of claim 1, wherein an upper surface of the semiconductor ring is above an upper surface of the vertical diode.

8. The structure of claim 1, further comprising a first contact to the vertical diode outside the semiconductor ring and a second contact to the vertical diode horizontally within the semiconductor ring, wherein the semiconductor ring is free of contacts thereto.

9. A structure comprising:
a PIN diode over a substrate, the PIN diode including:
a cathode over the substrate,
an intrinsic semiconductor on a second portion of the cathode, and
an anode on the intrinsic semiconductor, wherein the semiconductor ring horizontally surrounds the anode; and
a semiconductor ring over the cathode and horizontally surrounding the anode of the PIN diode, wherein a spacer material is horizontally adjacent the semiconductor ring and separates the semiconductor ring from the PIN diode, and wherein the semiconductor ring has the first conductivity type.

10. The structure of claim 9, further comprising an isolation layer vertically between the cathode of the PIN diode and the semiconductor ring, wherein an isolation layer is below the anode of the PIN diode.

11. The structure of claim 9, wherein the semiconductor ring is free of conductive contacts thereto.

12. The structure of claim 9, further comprising a bipolar transistor (BT) over the substrate and distal to the PIN diode, wherein an emitter of the BT and the semiconductor ring each include a doped polycrystalline semiconductor.

13. The structure of claim 9, further comprising a semiconductor pillar over the substrate and adjacent the PIN diode, wherein the semiconductor ring surrounds the PIN diode and the semiconductor pillar.

14. The structure of claim 9, wherein an upper surface of the semiconductor ring is above an upper surface of the PIN diode.

15. The structure of claim 9, further comprising a first contact to the cathode of the PIN diode outside the semiconductor ring and a second contact to the anode of the PIN diode inside the semiconductor ring, wherein the semiconductor ring is free of contacts thereto.

16. A method comprising:
forming a vertical diode over a substrate; and
forming a semiconductor ring over the substrate and horizontally surrounding the vertical diode, wherein a spacer material is horizontally adjacent the semiconductor ring and separates the semiconductor ring from the vertical diode.

17. The method of claim 16, further comprising forming an isolation layer vertically between a cathode of the vertical diode and the semiconductor ring, wherein the isolation layer is below an anode of the vertical diode.

18. The method of claim 16, further comprising forming a bipolar transistor (BT) over the substrate and distal to the vertical diode, wherein an emitter of the BT and the semiconductor ring each include a doped polycrystalline semiconductor.

19. The method of claim 16, further comprising forming a dielectric layer over the spacer material and the semiconductor ring, wherein the semiconductor ring is free of conductive contacts thereto.

20. The method of claim 16, further comprising forming a first contact to the vertical diode outside the semiconductor ring and forming a second contact to the vertical diode inside the semiconductor ring, wherein the semiconductor ring is free of contacts thereto.
